(19) United States
(12) Patent Application Publication
(10) Pub. No.: US 2026/0148905 A1
(43) Pub. Date: May 28, 2026

(54) DEVICE AND METHOD FOR PRODUCING ELECTRODE FOIL FOR ELECTROLYTIC CAPACITORS

(71) Applicant: Panasonic Intellectual Property Management Co., Ltd., Osaka (JP)

(72) Inventors: MIWA OGAWA, Osaka (JP); NAOMI KURIHARA, Osaka (JP)

(21) Appl. No.: 19/129,623

(22) PCT Filed: Nov. 16, 2023
(86) PCT No.: PCT/JP2023/041321

§ 371 Date: May 13, 2025

(30) Foreign Application Priority Data
Nov. 25, 2022 (JP) 2022-188129

(51) Int. Cl. H01G 13/00; C23C 16/455; H01G 9/00

(52) U.S. Cl. CPC H01G 13/00; C23C 16/45544; C23C 16/45555; H01G 9/0029

(57) ABSTRACT

A production device is a device that produces an electrode foil for an electrolytic capacitor. The production device includes: a conveyance mechanism that conveys a metal foil having a strip shape, the metal foil including a porous part; a head unit that supplies and removes a source gas for forming the dielectric layer on the porous part by an atomic layer deposition method; and a support belt that supports the metal foil in a film formation region where the dielectric layer is to be formed by the head unit. The dielectric layer is formed while the metal foil is being conveyed. The support belt includes a contact part in contact with the metal foil in the film formation region, the contact part being moved in a direction identical to a direction in which the metal foil is moved while the metal foil is supported in the film formation region.

### TECHNICAL FIELD

The present disclosure relates to a production device and a method for producing an electrode foil for an electrolytic capacitor.

### BACKGROUND

Electrode foil for an electrolytic capacitor includes an etching foil (metal foil) with a surface roughened by etching, and a dielectric layer covering the surface of the etching foil. The dielectric layer is generally formed by subjecting etching foil to an anodizing treatment (anodic oxidation). Meanwhile, formation of a dielectric layer by an atomic layer deposition method has also been proposed.

PTL 1 (US Publication No. 2013/0064977) discloses a method for forming an atomic layer on a substrate using a drum including a film forming head. This method is performed in which the substrate is conveyed to move around the drum.

PTL 2 (US Publication No. 2012/0196050) discloses a device in which a head is disposed on both sides of a substrate and atomic layers are simultaneously deposited on both the sides of the substrate. This device keeps a distance between the head and the substrate constant using a gas bearing.

### CITATION LIST

### Patent Literature

PTL 1: US Publication No. 2013/0064977

PTL 2: US Publication No. 2012/0196050

### SUMMARY

An aspect of the present disclosure relates to a production device that produces an electrode foil for an electrolytic capacitor. The production device includes: a conveyance mechanism that conveys a metal foil having a strip shape, the metal foil including a porous part on a surface of the metal foil; a head unit that supplies and removes a source gas for forming a dielectric layer on the porous part by an atomic layer deposition method; and a support belt that supports the metal foil from a side opposite to the head unit in a film formation region where the dielectric layer is to be formed by the head unit, the metal foil being interposed between the support belt and the head unit. The dielectric layer is formed while the metal foil is being conveyed, and the support belt includes a contact part in contact with the metal foil in the film formation region, the contact part being moved in a direction identical to a direction in which the metal foil is moved while the metal foil being moved is supported in the film formation region.

Another aspect of the present disclosure relates to a method for producing an electrode foil for an electrolytic capacitor. The method includes: a preparation step of setting a metal foil having a strip shape in a conveyance mechanism, the metal foil including a porous part on a surface of the metal foil; and a layer formation step of forming a dielectric layer on the porous part by an atomic layer deposition method while the metal foil is conveyed. The dielectric layer is formed using a head unit that supplies and removes a source gas for forming the dielectric layer. The layer formation step is performed in a film formation region where the dielectric layer is to be formed by the head unit while the metal foil is supported by a support belt from a side opposite to the head unit, the metal foil being interposed between the support belt and the head unit. In the layer formation step, the support belt includes a contact part in contact with the metal foil in the film formation region, the contact part being moved in a direction identical to a direction in which the metal foil is moved while the metal foil being moved is supported in the film formation region.

The present disclosure enables producing an electrode foil (an electrode foil for an electrolytic capacitor) on which a dielectric layer having high uniformity is formed.

### BRIEF DESCRIPTION OF THE DRAWINGS

FIG. 1 is a diagram schematically illustrating a configuration of an example of a production device according to a first exemplary embodiment.

FIG. 2 is a diagram schematically illustrating a configuration of an example of a part of the production device illustrated in FIG. 1.

FIG. 3 is a top view schematically illustrating an example of placement of metal foil and a support belt in the production device illustrated in FIG. 1.

FIG. 4 is a diagram schematically illustrating a configuration of another example of the production device according to the first exemplary embodiment.

FIG. 5 is a diagram schematically illustrating a configuration of an example of a production device according to a second exemplary embodiment.

### DESCRIPTION OF EMBODIMENT

When etching foil having a large surface area is used as a substrate in the method of PTL 1, a very long purge time is required. Thus, the number of nozzles (number of ALD cycles) that can be installed on a drum is limited. As a result, to secure the required number of cycles, the substrate needs to be very reduced in conveyance speed or the drum needs to be very increased in diameter. However, either way is not practical in terms of mass production.

PTL 2 shows a way in which a gap between the substrate and a nozzle is kept constant with the bearing gas. Unfortunately, when a wide and thin substrate such as etching foil is used, the gap is less likely to be kept constant, and thus a uniform film is less likely to be formed.

In such a situation, the present disclosure provides a device and a method for producing an electrode foil (an electrode foil for an electrolytic capacitor) provided with a dielectric layer having high uniformity.

Although exemplary embodiments according to the present disclosure will be described below with reference to examples, the present disclosure is not limited to the examples described below. Although specific numerical values and materials may be provided as examples in the description below, other numerical values and other materials may be applied as long as an effect of the present disclosure can be obtained. The description, “numerical value A to numerical value B” herein includes numerical value A and numerical value B, and can be read as “larger than or equal to numerical value A and smaller than or equal to numerical value B”. When an example of lower limits and upper limits of numerical values related to specific physical properties, conditions, or the like is described in the description below, any one of the lower limits described and any one of the upper limits described can be freely combined unless the one of the lower limits is equal to or more than the one of the upper limits. When examples of components or examples of methods are listed in the description below, only one of the listed examples may be used, or a plurality of examples of the listed examples may be used in combination, unless otherwise specified.

### (Production Device That Produces an Electrode Foil for Electrolytic Capacitors)

The device according to the present exemplary embodiment is a production device that produces an electrode foil for an electrolytic capacitor. The production device may be referred to below as “production device (D)”.

Production device (D) involves a metal foil including a porous part disposed on a surface of the metal foil, and a dielectric layer formed on the porous part. Production device (D) includes: a conveyance mechanism that conveys the metal foil having a strip shape, which includes the porous part on the surface of the metal foil; a head unit that supplies and removes a source gas for forming the dielectric layer on the porous part by an atomic layer deposition method (ALD method); and a support belt that supports the metal foil from a side opposite to the head unit in a film formation region where the dielectric layer is formed by the head unit. The metal foil is interposed between the support belt and the head unit. The dielectric layer is formed while the metal foil is being conveyed. The support belt includes a contact part in contact with the metal foil in the film formation region, the contact part being moved in a direction identical to a direction in which the metal foil is moved while the metal foil being moved is supported in the film formation region.

Production device (D) is configured to form the dielectric layer using the atomic layer deposition method, so that the dielectric layer can be formed with good uniformity up to a deep part of the porous part. Production device (D) enables the dielectric layer to be continuously formed on the metal foil in an elongated strip shape with high productivity. Production device (D) allows the metal foil to be supported by the support belt in the film formation region. Thus, a distance between the head unit and the metal foil can be made constant, and the dielectric layer having high uniformity can be stably formed. In particular, even when the metal foil has a wide width, the distance between the head unit and the metal foil can be easily made constant. Production device (D) further allows the contact part to be moved in a direction in which the metal foil is moved. Thus, the metal foil can be prevented from deteriorating due to friction or the like between the metal foil and a support table.

The metal foil is not particularly limited as long as it can be used for producing the electrode foil in production device (D). Production device (D) enables the dielectric layer to be formed on metal foil that is wide in width and long in length. The metal foil is not limited in width, and may have a width ranging from 5 cm (e.g., 15 cm) to 100 cm, inclusive. The metal foil is not limited in length, and may have a length ranging from 10 m (e.g., 30 m) to 2000 m, inclusive. The porous part in the surface of the metal foil may be formed by a publicly known method. For example, the porous part may be formed by etching a normal metal foil with a flat surface. Metal foil with a surface provided with the porous part is distributed, so that the metal foil may be used.

The metal foil usually includes a core part that is not porous and a porous part formed outside the core part. The porous part is usually formed in both surfaces (both principal surfaces) of the metal foil. However, when only one surface of the metal foil is used, the porous part may be formed only in one surface (one principal surface) of the metal foil. The porous part is not particularly limited in thickness, and has a thickness selected depending on an application of an electrolytic capacitor and required characteristics.

The porous part in one surface of the metal foil may have a thickness of more than or equal to 5 μm, more than or equal to 10 μm, more than or equal to 15 μm, or more than or equal to 50 μm. And the porous part in one surface of the metal foil may have a thickness of less than or equal to 200 μm, less than or equal to 150 μm, less than or equal to 100 μm, or less than or equal to 80 μm. When the metal foil is used as an anode of an electrolytic capacitor, from the viewpoint of capacitance, the porous part preferably has a thickness of more than or equal to 5 μm, and more preferably has a thickness of more than or equal to 15 μm. Further, from the viewpoint of strength of the metal foil, the porous part preferably has a thickness of less than or equal to 100 μm, and more preferably has a thickness of less than or equal to 80 μm. Here, the thickness of the porous part means a thickness formed in one principal surface of the metal foil. The thickness of the porous part can be measured by cutting the electrode foil (or the metal foil) and taking an electron micrograph of a cross section of the electrode foil.

The metal foil is made of metal (first metal). The first metal constituting the metal foil is not particularly limited in kind, and metal of the metal foil used for the electrode foil of the electrolytic capacitor can be used. Examples of the first metal include a valve metal and an alloy containing the valve metal. Examples of the valve metal include aluminum (Al), tantalum (Ta), and niobium (Nb).

The dielectric layer can be used for an electrode foil for an electrolytic capacitor. The dielectric layer is not particularly limited in thickness, and has a thickness selected in consideration of an application and characteristics of the electrolytic capacitor. The dielectric layer may have a thickness of more than or equal to 1 nm, or more than or equal to 5 nm, and may have a thickness of less than or equal to 300 nm, or less than or equal to 200 nm.

The dielectric layer may contain an oxide of metal (second metal) or may be an oxide of metal. The second metal contained in the dielectric layer may be the same as or different from the first metal. The second metal may be composed of the first metal and a metal other than the first metal.

Examples of the second metal include Al, Ta, Nb, silicon (Si), titanium (Ti), zirconium (Zr), and hafnium (Hf). The second metal may contain one kind of metal element or two or more kinds of metal elements. The dielectric layer may include at least one oxide selected from the group consisting of Al₂O₃, Ta₂O₅, Nb₂O₅, SiO₂, TiO₂, ZrO₂, and HfO₂. The dielectric layer may be formed of two or more layers different in composition. When the dielectric layer contains two or more kinds of oxides of the second metal, the two or more kinds of oxides may be mixed, or each of the two or more kinds of oxides may be disposed in a layer.

When the first metal and the second metal are different from each other, the oxide of the second metal preferably has a high relative dielectric constant than the oxide of the first metal from the viewpoint of increasing the capacitance of the electrolytic capacitor. One example of the metal foil contains the first metal of Al, and the second metal containing at least one selected from the group consisting of Ti, Si, Hf, Ta, and Nb. The second metal may contain Al and a metal other than Al.

The electrode foil produced by production device (D) may be used as an anode body on which a dielectric layer is formed, or may be used as other electrodes.

The conveyance mechanism is not particularly limited, and a conveyance mechanism similar to a conveyance mechanism used in a production method called roll-to-roll may be used. The support belt herein is not included in the conveyance mechanism. The conveyance mechanism usually includes an unwinding roll that feeds the metal foil that has been wound and a winding roll that winds the metal foil that has been fed. The dielectric layer is formed during conveyance from the unwinding roll to the winding roll.

A ratio Vm/Vb of a moving speed Vm of the metal foil in the film formation region to a moving speed Vb of the contact part in the film formation region may be in a range from 0.8 to 1.2, inclusive (e.g., in a range from 0.9 to 1.1, inclusive). When these speeds are set to be substantially equal or equal to each other, damage to the metal foil can be suppressed. Additionally, the metal foil can be easily and stably supported.

Production device (D) may further include a heater that heats the support belt. By heating the support belt, a film can be formed while the metal foil is heated by the support belt. This configuration enables the dielectric layer with high uniformity to be stably formed. The support belt needs to be heated to heat at least the contact part. A method for heating the support belt is not particularly limited, and a publicly known heating method may be used. For example, a method such as resistance heating, infrared heating, or induction heating may be used.

Production device (D) may further include a chamber surrounding the head unit, the metal foil passing through the film formation region, and the support belt passing through the film formation region. Film forming device (D) may further include a heater for heating the inside of the chamber. By heating the inside of the chamber, a dielectric layer with high uniformity can be stably formed.

A method for heating the inside of the chamber is not particularly limited, and a publicly known heating method may be used. For example, a method such as resistance heating, infrared heating, or induction heating may be used. The inside of the chamber may be heated from the inside of the chamber or from the outside. The unwinding roll and the winding roll are usually disposed outside the chamber. In this configuration, the metal foil passes through the inside of the chamber through a slit formed in the chamber. The inside of the chamber may be depressurized or may not be depressurized. This depressurization is determined depending on film formation conditions using an atomic layer deposition method.

Production device (D) may further include a suction mechanism for suctioning the metal foil to the support belt in the film formation region. This configuration enables a distance between the metal foil and the head unit to be made particularly constant, so that a dielectric layer with high uniformity can be formed. For the configuration, the moving speed Vm of the metal foil in the film formation region and the moving speed Vb of the contact part in the film formation region are preferably equal to each other.

Production device (D) may form the dielectric layer only on one surface (one principal surface) of the metal foil, or on both surfaces (both principal surfaces) of the metal foil. When the dielectric layer is formed on both the surfaces of the metal foil, the porous part includes a first porous part disposed in one principal surface of the metal foil and a second porous part disposed in the other principal surface of the metal foil.

When the dielectric layer is formed on both the surfaces of the metal foil, the dielectric layer (first dielectric layer) on one surface and the dielectric layer (second dielectric layer) on the other surface are usually formed to be substantially identical in thickness and composition. Meanwhile, since the dielectric layer is formed by an ALD method, the first dielectric layer and the second dielectric layer can be formed to have different thickness and/or composition from each other.

In a first example of the method for forming the dielectric layer on both the surfaces of the metal foil, at first, the metal foil with the dielectric layer formed on one surface is wound around the winding roll. Next, the wound metal foil is unwound to form a dielectric layer on the other surface of the metal foil in the film formation region. In this way, the dielectric layer can be formed on both the surfaces of the metal foil.

A second example of the method for forming the dielectric layer on both the surfaces of the metal foil will be described below. In the second example, the porous part includes the first porous part disposed on the one principal surface of the metal foil and the second porous part disposed on the other principal surface of the metal foil as described above. The head unit includes a first head unit that forms the dielectric layer on the first porous part, and a second head unit that forms the dielectric layer on the second porous part. The film formation region includes a first film formation region and a second film formation region. The support belt includes a first support belt that supports the metal foil in the first film formation region where the dielectric layer is to be formed by the first head unit, and a second support belt that supports the metal foil in a second film formation region where the dielectric layer is to be formed by the second head unit.

In the second example, the metal foil unwound from the unwinding roll passes through the first film formation region and the second film formation region, and then is wound by the winding roll. The first head unit and the second head unit each form the dielectric layer on a different surface of the metal foil. That is, the first head unit forms the dielectric layer on the first porous part, and the second head unit forms the dielectric layer on the second porous part. In the second example, production device (D) may include a mechanism for turning the metal foil upside down. For example, production device (D) may include a roll for turning the metal foil upside down. An example of a specific configuration of production device (D) in the second example will be described in a second exemplary embodiment described later

### (Method for Producing Electrode Foil for Electrolytic Capacitor)

A production method according to the present exemplary embodiment is a method for producing an electrode foil for an electrolytic capacitor. The production method may be referred to below as “production method (M)”. Production method (M) can be performed using production device (D). The matters described for production method (D) can be applied to production method (M), so that duplicated description may not be described. The matters described for production method (M) may be applied to production device (D). According to production method (M), the effects described in production device (D) can be exhibited.

Production method (M) includes a preparation step of setting a metal foil having a strip shape, which includes a porous part on a surface of the metal foil, in the conveyance mechanism, and a layer formation step of forming a dielectric layer on the porous part by the atomic layer deposition method while the metal foil is conveyed. The dielectric layer is formed using a head unit that supplies and removes a source gas for forming the dielectric layer. The layer formation step is performed in a film formation region where the dielectric layer is to be formed by the head unit while the metal foil is supported by a support belt from a side opposite to the head unit, the metal foil being interposed between the support belt and the head unit. In the layer formation step, the support belt includes a contact part in contact with the metal foil in the film formation region, the contact part being moved in a direction identical to a direction in which the metal foil is moved while the metal foil being moved is supported in the film formation region.

The preparation step is performed in which the unwinding roll around which the metal foil is wound is set in the conveyance mechanism, for example. An example of the layer formation step will be described later. Production method (M) may include a step other than the preparation step and the layer formation step.

The layer formation step in production method (M) is performed in which a ratio Vm/Vb of a moving speed Vm of the metal foil in the film formation region to a moving speed Vb of the contact part in the film formation region may be in a range from 0.8 to 1.2, inclusive (e.g., in a range from 0.9 to 1.1, inclusive).

In the layer formation step of production method (M), the support belt may be heated. In production method (M), the head unit, the metal foil passing through the film formation region, and the support belt passing through the film formation region may be surrounded by a chamber. Further, in the layer formation step, an inside of the chamber may be heated.

In production method (M), the layer formation step may be performed in a state that the metal foil is suctioned to the support belt in the film formation region.

As described in production device (D), production method (M) is performed in which the dielectric layer may be formed only on one surface of the metal foil, or the dielectric layer may be formed on both surfaces of the metal foil. Then, the dielectric layer may be formed as described in the first example and the second example described above.

An example of forming the dielectric layer as described in the second example will be described below. In this example, the porous part includes the first porous part disposed on the one principal surface of the metal foil and the second porous part disposed on the other principal surface of the metal foil. The head unit includes a first head unit that forms the dielectric layer on the first porous part, and a second head unit that forms the dielectric layer on the second porous part. The film formation region includes a first film formation region and a second film formation region. The support belt includes a first support belt that supports the metal foil in the first film formation region where the dielectric layer is to be formed by the first head unit, and a second support belt that supports the metal foil in a second film formation region where the dielectric layer is to be formed by the second head unit.

Examples of configurations of production device (D) and production method (M) will be described below. However, production device (D) and production method (M) are not limited to the examples described below. For a configuration other than a characteristic configuration of the present disclosure, a publicly known configuration of the atomic layer deposition method and a device used therefor may be applied.

### (Conveyance Mechanism)

The conveyance mechanism for conveying the metal foil is not particularly limited, and a known conveyance mechanism can be used. The conveyance mechanism may include the unwinding roll and the winding roll. The conveyance mechanism may include a roll for adjusting or changing a conveyance position and a conveyance direction of the metal foil, a mechanism for adjusting tension of the metal foil, and the like as necessary.

### (Head Unit)

The head unit includes a plurality of heads for supplying gas necessary for film formation, and an exhaust path for removing (recovering) the supplied gas and the like. Specifically, the head unit may include a first head for supplying a gas (source gas) of a precursor, a second head for supplying an oxidant, third heads for supplying an inert gas for purging the precursor, the oxidant, and the like, and a plurality of exhaust paths for removing the supplied gas and the like. The third heads may be disposed to sandwich each of the first head and the second head. The exhaust paths may be disposed to sandwich each of the first head, the second head, and the third head. One head group may include the first head, the second head, the third heads, and the exhaust paths. The one head group forms a dielectric layer in units of an atomic layer. In order to form the dielectric layer uniformly in a width direction of the metal foil, each of the first head, the second head, the third heads, and the exhaust paths extends in the width direction of the metal foil.

One head unit includes at least one head group, and usually includes a plurality of head groups. The plurality of head groups is disposed side by side from upstream to downstream of a conveyance path of the metal foil. Production device (D) may include a plurality of head units disposed side by side from upstream to downstream of the conveyance path of the metal foil. By increasing the number of head units and/or the number of head groups, a thickness of the dielectric layer can increased. A number of the head groups included in one head unit may be in a range from 1 to 700, inclusive (e.g., a range from 1 to 200, inclusive).

The first head and the second head are connected to a device for supplying a material to be supplied. For example, the first head unit may be connected to a gas cylinder for the precursor or the like through a mass flow controller. Each head unit includes channels for supplying the precursor or the oxidant. Each of the channels may be in the shape of a nozzle. Alternatively, each of the channels may be a through hole formed in a member having a plate shape. In order to form the dielectric layer with good uniformity throughout the metal foil in the width direction, the channels are preferably disposed uniformly in the width direction. For example, one through hole extending in the width direction may serve as the channel. Alternatively, a plurality of through-holes disposed at constant intervals in the width direction may serve as the channels. The exhaust path is connected to an exhaust device. These devices are not particularly limited, and publicly known devices may be used.

Production device (D) may include a moving mechanism that moves the head unit to reciprocate along the conveyance direction of the metal foil. Then, the dielectric layer may be formed by moving the head unit. This configuration enables a thick dielectric layer to be formed with a small head group, and thus enables the device to be downsized.

### (Support Belt)

The support belt preferably supports substantially the entire metal foil in the film formation region. Specifically, a part having an area of 80% or more (e.g., 90% or more) in an area of the entire metal foil in the film formation region is preferably supported, or the entire metal foil in the film formation region may be supported. Preferably, the support belt has a width greater than a width of the metal foil, and supports an entire lower surface of the metal foil in the film formation region.

Although a material of the support belt is not particularly limited, the support belt is preferably mainly made of metal from the viewpoint of heating the metal foil. An endless belt is available for the support belt. The support belt may be an endless single metal sheet. Alternatively, the support belt may be formed by arranging and connecting a plurality of elongated sheets along a circumferential direction of the belt.

The support belt is usually disposed below the metal foil, and the head unit is usually disposed above the metal foil. Thus, the support belt can support the metal foil without using a suction mechanism or the like. As described above, the support belt may suction the metal foil in the film formation region. For the suction, the support belt includes a suction mechanism. The suction mechanism is not particularly limited, and a publicly known method for suctioning an article conveyed by a belt conveyor or the like may be used. One example of the suction mechanism uses a support belt provided with many fine through-holes, and includes the suction mechanism with a depressurizing mechanism that depressurizes the through-holes in the contact part. This configuration causes the metal foil in contact with the contact part to be suctioned. Alternatively, the suction mechanism may suction the metal foil by static electricity. That is, the suction mechanism may suction the metal foil by depressurization and/or static electricity.

Production device (D) includes at least one film formation region. Production device (D) includes at least one head unit and at least one support belt. When production device (D) includes a plurality of film formation regions, production device (D) includes a plurality of head units. In this case, production device (D) may include a plurality of support belts. Alternatively, production device (D) may include one support belt extending over a plurality of film formation regions.

### (Layer Formation Step)

The dielectric layer is formed covering at least a part of the porous part. The dielectric layer is typically formed covering the entire porous parts present on one side or both sides of a part of the metal foil, the part being used as an electrode.

When the dielectric layer is formed by an anodizing treatment, metal constituting the metal foil is contained in the dielectric layer. In contrast, the dielectric layer is formed by the atomic layer deposition method in production device (D) and production method (M), so that an oxide of metal different from the metal of the metal foil can be used for the dielectric layer. Thus, a range of selection of the second metal is widened, so that various performances can be imparted to the dielectric layer.

An example of performing the layer formation step by the ALD method will be described below. The dielectric layer is formed while the metal foil is conveyed in the film formation region. The metal foil conveyed in the film formation region may be heated to a predetermined temperature as necessary. The metal foil may be heated to a range from 80° C. to 550° C., inclusive (e.g., a range from 90° C. to 400° C., inclusive) as necessary. The film formation region may be depressurized or under atmospheric pressure.

In the layer formation step, at first, a precursor gas (source gas) is supplied from the first head to the surface (porous part) of the metal foil. The precursor is deposited in units of an atomic layer. Next, an unnecessary precursor and the like are removed (purged). Subsequently, an oxidizing agent is supplied from the second head to the surface of the metal foil. Then, an unnecessary oxidizing agent and a substance generated by reaction are removed (purged). One cycle is defined including the supply of a precursor, the purge of the precursor, the supply of the oxidant, and the purge of the oxidant. An extremely thin dielectric layer is formed in the one cycle. Corresponding to the one cycle, one head group includes a first head for supplying the precursor, a second head for supplying the oxidant, a third head for supplying an inert gas for purging, and a plurality of exhaust paths for exhausting the supplied gas and the like. By increasing the number of head groups included in one head unit, a thickness of the dielectric layer which is to be formed by the one head unit can be increased. Further, by increasing the number of head units, the a thickness of the dielectric layer which is to be formed can be increased.

The precursor is selected suitable for composition of the dielectric layer. For the precursor, an organic compound containing the second metal contained in the dielectric layer is available. The organic compound is not particularly limited, and an organic compound conventionally used in the ALD method may be used.

Examples of the precursor containing Al include trimethylaluminum ((CH₃)₃Al). Examples of the precursor containing Ta include (t-butylimide) tris (ethylmethylamino) tantalum (V) (C₁₃H₃₃N₄Ta, TBTEMT), and tantalum (V) pentaethoxide (Ta(OC₂H₅)₅).

Examples of the precursor containing Nb include niobium (V) ethoxide (Nb(OCH₂CH₃)₅, and tris(diethylamide)(t-butylimide) niobium (V) (C₁₆H₃₉N₄Nb). Examples of the precursor containing Si include N-sec-butyl (trimethylsilyl) amine (C₇H₁₉NSi), tetraethylsilane (Si (C₂H₅)₄), tetraethoxysilane (Si (OC₂H₅)₄), and silicon tetrachloride (SiCl₄).

Examples of the precursor containing Ti include tetrakis (dimethylamino) titanium (IV) ([(CH₃)₂N]₄Ti, TDMAT), titanium tetrachloride (TiCl₄), and titanium (IV) ethoxide (Ti [O (C₂H₅)]₄). Examples of the precursor containing Zr include tetrakis (ethylmethylamide) zirconium (IV) (Zr (NCH₃C₂H₅)₄) and zirconium (IV) t-butoxide (Zr [OC (CH₃)₃]₄).

Examples of the precursor containing Hf include hafniumtetrachloride (HfCl₄), tetrakisdimethylaminohafnium (Hf[N(CH₃)₂]₄) and hafnium-t-butoxide (Hf[OC(CH₃)₃]₄).

Examples of the oxidant include water, oxygen, and ozone. The oxidant may be supplied to the surface of the metal foil as plasma using the oxidant as a raw material. The inert gas for purging is not particularly limited, and a publicly known inert gas (e.g., nitrogen gas) can be used.

An example of production device (D) and an example of production method (M) using the device will be specifically described below with reference to the drawings. The examples described below can be modified based on the above description. Matters described below may be applied to the exemplary embodiment described above.

### FIRST EXEMPLARY EMBODIMENT

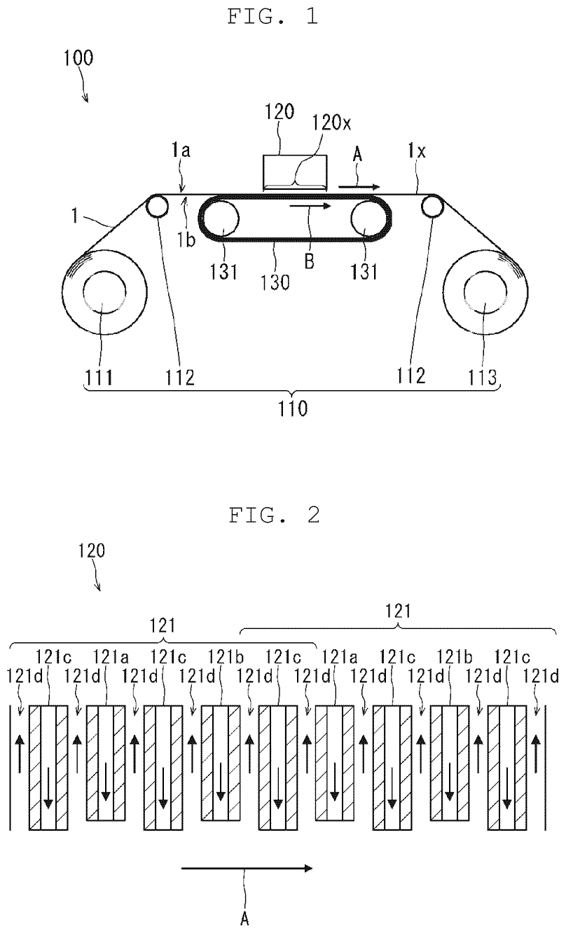

In a first exemplary embodiment, an example of production device (D) will be described. FIG. 1 schematically illustrates a configuration of production device 100 of the first exemplary embodiment. Production device 100 includes conveyance mechanism 110, head unit 120, and support belt 130. Production device 100 may include a chamber (the same applies to a production device below). The chamber may be disposed surrounding at least a part of conveyance mechanism 110, head unit 120, and support belt 130, or may be disposed surrounding all of them.

Conveyance mechanism 110 includes unwinding roll 111, position adjusting roll 112, and winding roll 113. The metal foil is wound by the winding roll 113, and the metal foil is simultaneously unwound by the unwinding roll 111 to convey the metal foil in a direction of arrow A.

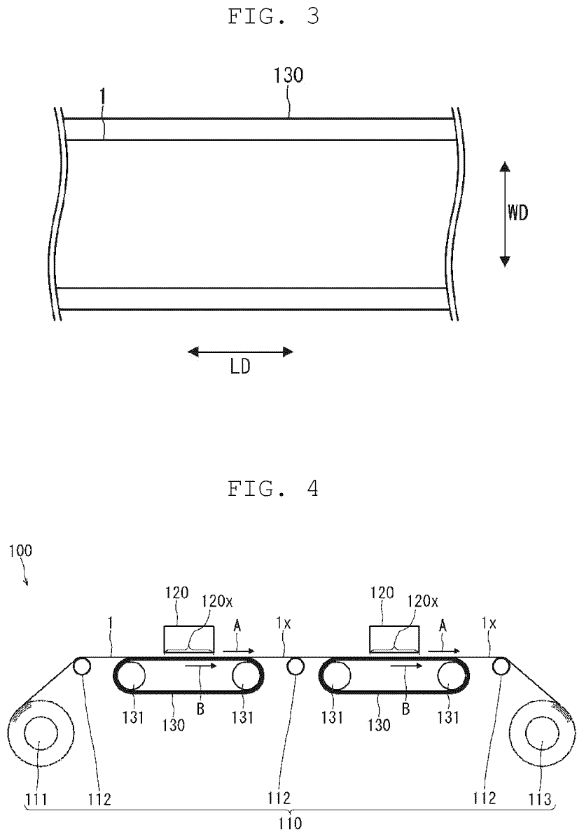

FIG. 2 is an enlarged view schematically illustrating a configuration of head unit 120. In FIG. 2, the conveyance direction of the metal foil indicates with arrow A. Although head unit 120 includes two head groups 121 disposed side by side along the conveyance direction of the metal foil in an example illustrated in FIG. 2, head unit 120 may include more head groups. Each of head groups 121 includes first head 121a, second head 121b, a plurality of third heads 121c, and a plurality of exhaust paths 121d. Each of arrows in the respective heads and exhaust paths indicates a flow of gas. In head unit 120 of the example illustrated in FIG. 2, two adjacent head groups 121 share third head 121c and exhaust path 121d between second head 121b of head groups 121 at upstream and first head 121a of head groups 121 at downstream. Alternatively, the two adjacent head groups 121 may each include third head 121c and exhaust path 121d without sharing them. First head 121a and second head 121b are disposed side by side in this order from upstream to downstream in the conveyance direction of the metal foil. As described above, first head 12la is for supplying a precursor, second head 121b is for supplying an oxidant, and third head 121c is for supplying a gas for purging. Positions of the respective heads and exhaust paths are changed depending on film formation conditions and the like. For example, when a film is formed while head unit 120 is moved along the conveyance direction of the metal foil, the first head 121a may be disposed upstream or downstream of second head 121b in one head group.

To form the dielectric layer, at first, metal foil 1 having a strip shape, which includes a porous part on a surface of metal foil 1, is set in the conveyance mechanism. Specifically, unwinding roll 111 around which the metal foil 1 is wound is set at a predetermined position. When metal foil 1 is unwound from unwinding roll 111 and passes through film formation region 120x, a dielectric layer is formed on one principal surface la (surface facing head unit 120) of the metal foil. Film formation region 120x is a region below head unit 120 (a region between head unit 120 and metal foil 1). Metal foil 1x (electrode foil) provided with the dielectric layer is wound around winding roll 113. In this way, an electrode foil for an electrolytic capacitor is produced.

The dielectric layer is formed by the atomic layer deposition method while metal foil 1 is conveyed (layer formation step). The layer formation step is performed while metal foil 1 is supported by support belt 130 from a side opposite to head unit 120, metal foil 1 being interposed between support belt 130 and head unit 120 in film formation region 120x where the dielectric layer is formed by head unit 120. Specifically, metal foil 1 is supported by support belt 130 from below. Head unit 120 is disposed above metal foil 1.

Support belt 130 is an endless belt, and is rotated in a direction of arrow B by rotating rolls 131 disposed at its both ends. That is, support belt 130 includes a contact part in contact with metal foil 1 in film formation region 120x, the contact part being moved in a direction identical to a direction in which metal foil 1 is moved while metal foil 1 is supported in film formation region 120x when the dielectric layer is formed. A roll (a roll other than roll 131) or the like for supporting support belt 130 may be disposed inside support belt 130.

FIG. 3 schematically illustrates a top view of metal foil 1 and support belt 130 in film formation region 120x as viewed from above head unit 120. FIG. 3 illustrates width direction WD and longitudinal direction LD of metal foil 1. Support belt 130 has a width greater than a width of metal foil 1, and supports the entire lower surface of metal foil 1 in film formation region 120x.

When the dielectric layer is also formed on the other surface of metal foil 1x, metal foil 1x wound with another principal surface 1b facing head unit 120 is conveyed to film formation region 120x. In film formation region 120x, the dielectric layer can be formed on principal surface 1b.

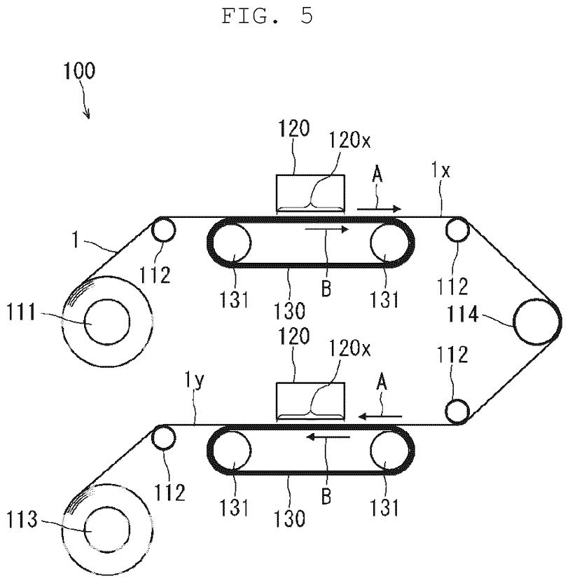

As described above, production device 100 may include a plurality of head units 120. FIG. 4 schematically illustrates an example of a configuration of production device 100 including two head units 120. Production device 100 of FIG. 4 includes two head units 120 (two film formation regions 120x) and two support belts 130. Alternatively, one support belt 130 across two film formation regions 120x may be used instead of two support belts 130.

### SECOND EXEMPLARY EMBODIMENT

The second exemplary embodiment is described in which dielectric layers are formed on both surfaces of metal foil 1 conveyed from unwinding roll 111, and metal foil 1y (electrode foil) including the dielectric layers formed on both surfaces is wound by winding roll 113.

FIG. 5 schematically illustrates a configuration of an example of a production device used in the second exemplary embodiment. Production device 100a of FIG. 5 is different from the production devices illustrated in FIGS. 1 and 4 only in that a dielectric layer is formed by inverting metal foil 1x, and thus duplicated description may not be described.

Production device 100a includes conveyance mechanism 110, two head units (first head unit and second head unit) 120, and two support belts 130. Production device 100a includes two film formation regions 120x. The conveyance mechanism includes unwinding roll 111, position adjusting roll 112, winding roll 113, and reversing roll 114. Reversing roll 114 is for turning the metal foil upside down.

To form the dielectric layer, at first, unwinding roll 111 around which metal foil 1 having a strip shape, which includes a porous part on a surface of metal foil 1, is wound is set at a predetermined position as described in FIG. 1. Next, metal foil 1 is unwound from unwinding roll 111. Metal foil 1 first passes though first film formation region 120x in which the dielectric layer is formed on one surface (upper surface) of metal foil 1. Subsequently, metal foil 1x provided with the dielectric layer is inverted by reversing roll 114. Thus, the surface provided with no dielectric layer becomes the upper surface of metal foil 1x. Metal foil 1x next passes through second film formation region 120x in which the dielectric layer is formed on the other surface (upper surface) of metal foil 1. In this way, metal foil 1y with both the surfaces provided with the dielectric layers is obtained. Metal foil 1y is wound by winding roll 113. In this way, electrode foil for an electrolytic capacitor is produced. Production device 100a may include a plurality of head units 120 for forming a dielectric layer on one surface of metal foil 1, and may include a plurality of head units 120 for forming a dielectric layer on the other surface of metal foil 1.

### (Supplementary Note)

Techniques below are disclosed by the above description.

### (Technique 1)

A production device that produces an electrode foil for an electrolytic capacitor, the production device including:
a conveyance mechanism that conveys a metal foil having a strip shape, the metal foil including a porous part on a surface of the metal foil;
a head unit that supplies and removes a source gas for forming a dielectric layer on the porous part by an atomic layer deposition method; and
a support belt that supports the metal foil from a side opposite to the head unit in a film formation region where the dielectric layer is to be formed by the head unit, the metal foil being interposed between the support belt and the head unit.

The dielectric layer is formed while the metal foil is being conveyed, and
the support belt includes a contact part in contact with the metal foil in the film formation region, the contact part being moved in a direction identical to a direction in which the metal foil is moved while the metal foil being moved is supported in the film formation region.

### (Technique 2)

The production device described in Technique 1, in which a ratio Vm/Vb of a moving speed Vm of the metal foil in the film formation region to a moving speed Vb of the contact part in the film formation region is in a range from 0.9 to 1.1, inclusive.

### (Technique 3)

The production device described in Technique 1 or 2, further including a heater that heats the support belt.

### (Technique 4)

The production device described in any one of Techniques 1 to 3, further including:
a chamber surrounding the head unit, the metal foil passing through the film formation region, and the support belt passing through the film formation region; and
a heater for heating an inside of the chamber

### (Technique 5)

The production device described in any one of Techniques 1 to 4, further including a suction mechanism for suctioning the metal foil to the support belt in the film formation region.

### (Technique 6)

The production device described in any one of Techniques 1 to 5, in which
the porous part includes a first porous part disposed on one principal surface of the metal foil and a second porous part disposed on another principal surface of the metal foil,
the head unit includes a first head unit that forms the dielectric layer on the first porous part, and a second head unit that forms the dielectric layer on the second porous part,
the film formation region includes a first film formation region and a second film formation region, and
the support belt includes a first support belt that supports the metal foil in the first film formation region where the dielectric layer is to be formed by the first head unit, and a second support belt that supports the metal foil in the second film formation region where the dielectric layer is to be formed by the second head unit.

### (Technique 7)

A method for producing an electrode foil for an electrolytic capacitor, the method including:
a preparation step of setting a metal foil having a strip shape in a conveyance mechanism, the metal foil including a porous part on a surface of the metal foil; and
a layer formation step of forming a dielectric layer on the porous part by an atomic layer deposition method while the metal foil is conveyed.

The dielectric layer is formed using a head unit that supplies and removes a source gas for forming the dielectric layer,
the layer formation step is performed in a film formation region where the dielectric layer is to be formed by the head unit while the metal foil is supported by a support belt from a side opposite to the head unit, the metal foil being interposed between the support belt and the head unit, and
in the layer formation step, the support belt includes a contact part in contact with the metal foil in the film formation region, the contact part being moved in a direction identical to a direction in which the metal foil is moved while the metal foil being moved is supported in the film formation region.

### (Technique 8)

The method described in Technique 7, in which a ratio Vm/Vb of a moving speed Vm of the metal foil in the film formation region to a moving speed Vb of the contact part in the film formation region is in a range from 0.9 to 1.1, inclusive, in the layer formation step.

### (Technique 9)

The method described in Technique 7 or 8, in which the support belt is heated in the layer formation step.

### (Technique 10)

The method described in any one of Techniques 7 to 9, in which
the head unit, the metal foil passing through the film formation region, and the support belt passing through the film formation region are surrounded by a chamber, and
an inside of the chamber is heated in the layer formation step.

### (Technique 11)

The method described in any one of Techniques 7 to 10, in which the layer formation step is performed while the metal foil is suctioned to the support belt in the film formation region.

### (Technique 12)

The method described in any one of Techniques 7 to 11, in which:
the porous part includes a first porous part disposed on one principal surface of the metal foil and a second porous part disposed on another principal surface of the metal foil,
the head unit includes a first head unit that forms the dielectric layer on the first porous part, and a second head unit that forms the dielectric layer on the second porous part,
the film formation region includes a first film formation region and a second film formation region, and
the support belt includes a first support belt that supports the metal foil in the first film formation region where the dielectric layer is to be formed by the first head unit, and a second support belt that supports the metal foil in the second film formation region where the dielectric layer is to be formed by the second head unit.

### INDUSTRIAL APPLICABILITY

The present disclosure can be used in a device and a method for producing electrode foil for an electrolytic capacitor.

### REFERENCE MARKS IN THE DRAWINGS

1 metal foil
1x, 1y metal foil (electrode foil)
100, 100a production device
110 conveyance mechanism
120 head unit
120x film formation region
121a first head
121c second head
130 support belt

1. A production device that produces an electrode foil for an electrolytic capacitor, the production device comprising:
a conveyance mechanism that conveys a metal foil having a strip shape, the metal foil including a porous part on a surface of the metal foil;
a head unit that supplies and removes a source gas for forming a dielectric layer on the porous part by an atomic layer deposition method; and
a support belt that supports the metal foil from a side opposite to the head unit in a film formation region where the dielectric layer is to be formed by the head unit, the metal foil being interposed between the support belt and the head unit,
wherein:
the dielectric layer is formed while the metal foil is being conveyed, and
the support belt includes a contact part in contact with the metal foil in the film formation region, the contact part being moved in a direction identical to a direction in which the metal foil is moved while the metal foil is supported in the film formation region.

2. The production device according to claim 1, wherein a ratio Vm/Vb of a moving speed Vm of the metal foil in the film formation region to a moving speed Vb of the contact part in the film formation region is in a range from 0.9 to 1.1, inclusive.

3. The production device according to claim 1, further comprising a heater that heats the support belt.

4. The production device according to claim 1, further comprising:
a chamber surrounding the head unit, the metal foil passing through the film formation region, and the support belt passing through the film formation region; and
a heater for heating an inside of the chamber.

5. The production device according to claim 1, further comprising a suction mechanism for suctioning the metal foil to the support belt in the film formation region.

6. The production device according to claim 1, wherein:
the porous part includes a first porous part disposed on one principal surface of the metal foil and a second porous part disposed on another principal surface of the metal foil,
the head unit includes a first head unit that forms the dielectric layer on the first porous part, and a second head unit that forms the dielectric layer on the second porous part,
the film formation region includes a first film formation region and a second film formation region, and
the support belt includes a first support belt that supports the metal foil in the first film formation region where the dielectric layer is to be formed by the first head unit, and a second support belt that supports the metal foil in the second film formation region where the dielectric layer is to be formed by the second head unit.

7. A method for producing an electrode foil for an electrolytic capacitor, the method comprising:
a preparation step of setting a metal foil having a strip shape in a conveyance mechanism, the metal foil including a porous part on a surface of the metal foil; and
a layer formation step of forming a dielectric layer on the porous part by an atomic layer deposition method while the metal foil is conveyed,
wherein:
the dielectric layer is formed using a head unit that supplies and removes a source gas for forming the dielectric layer,
the layer formation step is performed in a film formation region where the dielectric layer is to be formed by the head unit while the metal foil is supported by a support belt from a side opposite to the head unit, the metal foil being interposed between the support belt and the head unit, and
in the layer formation step, the support belt includes a contact part in contact with the metal foil in the film formation region, the contact part being moved in a direction identical to a direction in which the metal foil is moved while the metal foil is supported in the film formation region.

8. The method according to claim 7, wherein a ratio Vm/Vb of a moving speed Vm of the metal foil in the film formation region to a moving speed Vb of the contact part in the film formation region is in a range from 0.9 to 1.1, inclusive, in the layer formation step.

9. The method according to claim 7, wherein the support belt is heated in the layer formation step.

10. The method according to claim 7, wherein:
the head unit, the metal foil passing through the film formation region, and the support belt passing through the film formation region are surrounded by a chamber, and
an inside of the chamber is heated in the layer formation step.

11. The method according to claim 7, wherein the layer formation step is performed while the metal foil is suctioned to the support belt in the film formation region.

12. The method according to claim 7, wherein:
the porous part includes a first porous part disposed on one principal surface of the metal foil and a second porous part disposed on another principal surface of the metal foil,
the head unit includes a first head unit that forms the dielectric layer on the first porous part, and a second head unit that forms the dielectric layer on the second porous part,
the film formation region includes a first film formation region and a second film formation region, and
the support belt includes a first support belt that supports the metal foil in the first film formation region where the dielectric layer is to be formed by the first head unit, and a second support belt that supports the metal foil in the second film formation region where the dielectric layer is to be formed by the second head unit.
